(19) United States
(12) Patent Application Publication
(10) Pub. No.: US 2026/0293245 A1
(43) Pub. Date: Sep. 24, 2026

(54) NANORIBBON-BASED TRANSISTOR WITH WIDE SOURCE OR DRAIN REGION BELOW NANORIBBON STACK

(71) Applicant: Intel Corporation, Santa Clara, CA (US)

(72) Inventors: Feng Zhang, Portland, OR (US); Guowei Xu, Portland, OR (US); Tao Chu, Portland, OR (US); Chun Wing Yeung, Portland, OR (US); Kan Zhang, Hillsboro, OR (US); Yang Zhang, Rio Rancho, NM (US); Yanbin Luo, Portland, OR (US); Chung-Hsun Lin, Portland, OR (US); Ting-Hsiang Hung, Beaverton, OR (US); Lin Hu, Portland, OR (US); Jae Hur, Hillsboro, OR (US); Michal Mleczko, Portland, OR (US); Qiwen Wang, Portland, OR (US); Tahir Ghani, Portland, OR (US); Chia-Ching Lin, Portland, OR (US)

(73) Assignee: Intel Corporation, Santa Clara, CA (US)

(21) Appl. No.: 19/082,545

(22) Filed: Mar. 18, 2025

(51) Int. Cl. H10D 62/13; H10D 30/00; H10D 30/01; H10D 30/47; H10D 62/10; H10D 84/85

(52) U.S. Cl. CPC H10D 62/151; H10D 30/017; H10D 30/0191; H10D 30/47; H10D 30/502; H10D 62/118; H10D 84/851

(57) ABSTRACT

In accordance with examples described herein, an integrated circuit (IC) structure including a nanoribbon-based transistor with a wide source/drain (S/D) region below the nanoribbon stack may improve the process window for backside lithography and etch processes used to form backside S/D contacts. In one example, an S/D opening (e.g., source opening) is enlarged (e.g., widened), and a large and/or deep S/D region may be formed, which may increase the process margin for the lithography and etch processes used to form a backside S/D contact. In one example, for an S/D region without a backside contact (e.g., a drain opening), the bottom of the S/D opening may be filled with an insulator material, which may reduce the incidence of shorts between the S/D region and backside metal lines.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize fabrication and performance of each component is becoming increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 provides a perspective view of an example nanoribbon field-effect transistor (FET), according to one embodiment of the present disclosure.

FIG. 2 is a flow diagram of an example method for fabricating an IC structure including a nanoribbon-based transistor with a wide S/D region below the nanoribbon stack, in accordance with some embodiments.

FIGS. 3A-3P provide cross-sectional side views at various stages in the fabrication of an example IC structure according to the method of FIG. 2, in accordance with some embodiments.

FIG. 4 is a top view of a wafer and dies that may include any of the IC devices disclosed herein, in accordance with any of the embodiments disclosed herein.

FIG. 5 is a side, cross-sectional view of an IC package that may include any of the IC devices disclosed herein, in accordance with various embodiments.

FIG. 6 is a side, cross-sectional view of an IC device assembly that may include any of the IC devices disclosed herein, in accordance with any of the embodiments disclosed herein.

FIG. 7 is a block diagram of an example electrical device that may include any of the IC devices disclosed herein, in accordance with any of the embodiments disclosed herein.

### DETAILED DESCRIPTION

Disclosed herein are IC structures and devices including a nanoribbon-based transistor with a wide S/D region below the nanoribbon stack. The systems, methods, and devices of this disclosure each have several innovative aspects, no single one of which is solely responsible for all desirable attributes disclosed herein. Details of one or more implementations of the subject matter described in this specification are set forth in the description below and the accompanying drawings.

For purposes of illustrating fabrication of nanoribbon-based transistors with a wide S/D region below the nanoribbon stack, described herein, it might be useful to first understand phenomena that may come into play during IC fabrication. The following foundational information may be viewed as a basis from which the present disclosure may be properly explained. Such information is offered for purposes of explanation only and, accordingly, should not be construed in any way to limit the broad scope of the present disclosure and its potential applications.

Non-planar transistors such as double-gate transistors, tri-gate transistors, FinFETs, and nanowire/nanoribbon/nanosheet transistors refer to transistors having a non-planar architecture. In comparison to a planar architecture where the transistor channel has only one confinement surface, a non-planar architecture is any type of architecture where the transistor channel has more than one confinement surface. A confinement surface refers to a particular orientation of the channel surface that is confined by the gate field. Non-planar transistors potentially improve performance relative to transistors having a planar architecture, such as single-gate transistors.

Nanoribbon-based transistors may be particularly advantageous for continued scaling of metal-oxide-semiconductor (MOS) technology nodes due to the potential to form gates on all four sides of a channel material (hence, such transistors are sometimes referred to as “gate all around” transistors). As used herein, the term “nanoribbon” refers to an elongated structure of a semiconductor material having a longitudinal axis parallel to a support structure (e.g., a substrate, a die, a chip, or a wafer; also referred to herein as, simply, “support”) over which such a structure is built. Typically, a length of a such a structure (i.e., a dimension measured along the longitudinal axis, shown in the present drawings to be along the y-axis of an example x-y-z coordinate system) is greater than each of a width (i.e., a dimension measured along the x-axis of the example coordinate system shown in the present drawings) and a thickness (i.e., a dimension measured along the z-axis of the example coordinate system shown in the present drawings). In some settings, the terms “nanoribbon” or “nanosheet” have been used to describe elongated semiconductor structures that have a rectangular transverse cross-section (i.e., a cross-section in a plane perpendicular to the longitudinal axis of the structure), while the term “nanowire” has been used to describe similar elongated structures but with circular transverse cross-sections. In the present disclosure, the term “nanoribbon” is used to refer to all such nanowires, nanoribbons, and nanosheets, as well as elongated semiconductor structures with a longitudinal axis parallel to the support structures and with having transverse cross-sections of any geometry (e.g., transverse cross-sections in the shape of an oval or a polygon with rounded corners). A transistor may then be described as a “nanoribbon-based transistor” if the channel of the transistor is a portion of a nanoribbon, i.e., a portion around which a gate stack of a transistor may wrap around. The semiconductor material in the portion of the nanoribbon that forms a channel of a transistor may be referred to as a “channel material,” with source and drain (S/D) regions of a transistor provided on either side of the channel material.

Conventionally, S/D contact structures may be formed over the S/D region on the front side of the wafer. In some examples, an IC structure may also, or alternatively, include one or more backside S/D contacts. For example, after forming a frontside source contact and a frontside drain contact, the IC structure may be flipped over, and a backside source and/or drain contact may be formed. Forming backside S/D contacts may be challenging due to, for example, backside lithography alignment. Additionally, an etching process to expose the S/D region from the backside may result in yield loss due to shorts between the metal gate and the S/D contact. Furthermore, shorts may occur between backside metal lines and an S/D region without a backside contact.

In accordance with examples described herein, an IC structure including a nanoribbon-based transistor with a wide S/D region below the nanoribbon stack may improve the process window for backside lithography and etch processes used to form backside S/D contacts. In one example, an S/D opening (e.g., source opening) is enlarged (e.g., widened), and a large and/or deep S/D region may be formed, which may increase the process margin for the lithography and etch processes used to form a backside S/D contact. In one example, for an S/D region without a backside contact (e.g., a drain opening), the bottom of the S/D opening may be filled with an insulator material, which may reduce the incidence of shorts between the S/D region and backside metal lines.

IC structures as described herein, in particular IC structures including a nanoribbon-based transistor with a wide S/D region below the nanoribbon stack, may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of a radio frequency (RF) receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials, and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of the presence of IC structures including a nanoribbon-based transistor with a wide S/D region below the nanoribbon stack as described herein.

Various aspects of the illustrative implementations will be described using terms commonly employed by those skilled in the art to convey the substance of their work to others skilled in the art. For example, the terms “oxide,” “carbide,” “nitride,” “silicide,” etc. refer to compounds containing, respectively, oxygen, carbon, nitrogen, silicon, etc.; the term “high-k dielectric” refers to a material having a higher dielectric constant than silicon oxide; the term “low-k dielectric” refers to a material having a lower dielectric constant than silicon oxide. Materials referred to herein with formulas or as compounds cover all materials that include elements of the formula or a compound, e.g., TiSi or titanium silicide may refer to any material that includes titanium and silicon, WN or tungsten nitride may refer to any material that includes tungsten and nitrogen, etc. The term “insulating” means “electrically insulating,” the term “conducting” means “electrically conducting,” unless otherwise specified. Furthermore, the term “connected” may be used to describe a direct electrical or magnetic connection between the things that are connected, without any intermediary devices, while the term “coupled” may be used to describe either a direct electrical or magnetic connection between the things that are connected, or an indirect connection through one or more passive or active intermediary devices. A first component described to be electrically coupled to a second component means that the first component is in conductive contact with the second component (i.e., that a conductive pathway is provided to route electrical signals/power between the first and second components).

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

IC structures including a nanoribbon-based transistor with a wide S/D region below the nanoribbon stack described herein may include transistors of any architecture, such as any non-planar or planar architecture. Non-planar transistors such as double-gate transistors, tri-gate transistors, FinFETs, and nanowire/nanoribbon/nanosheet transistors refer to transistors having a non-planar architecture. In comparison to a planar architecture where the transistor channel has only one confinement surface, a non-planar architecture is any type of architecture where the transistor channel has more than one confinement surface. A confinement surface refers to a particular orientation of the channel surface that is confined by the gate field. Non-planar transistors potentially improve performance relative to transistors having a planar architecture, such as single-gate transistors.

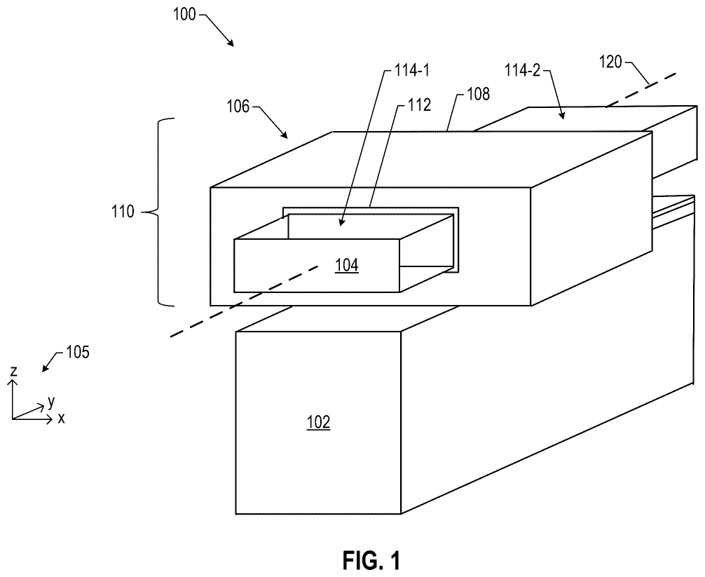

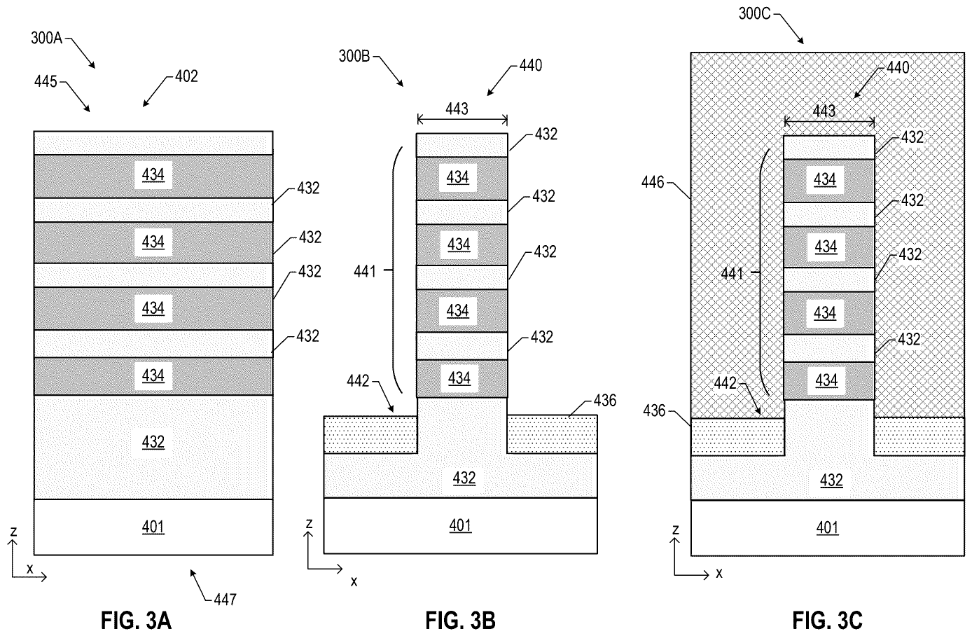

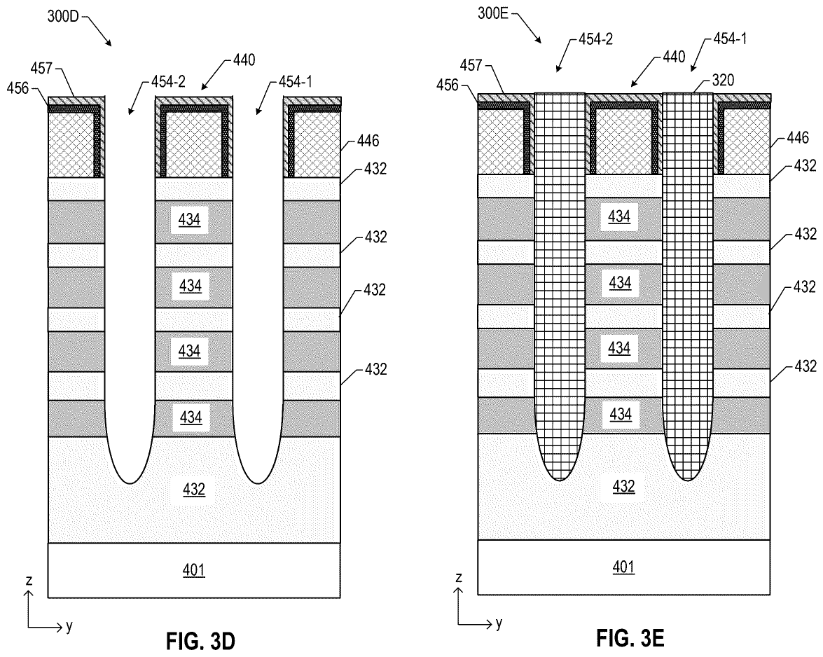

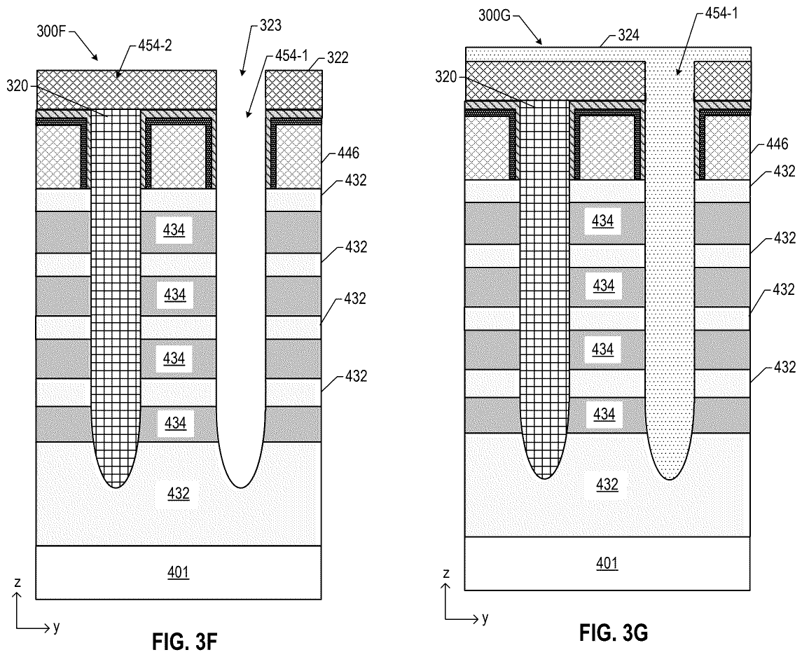

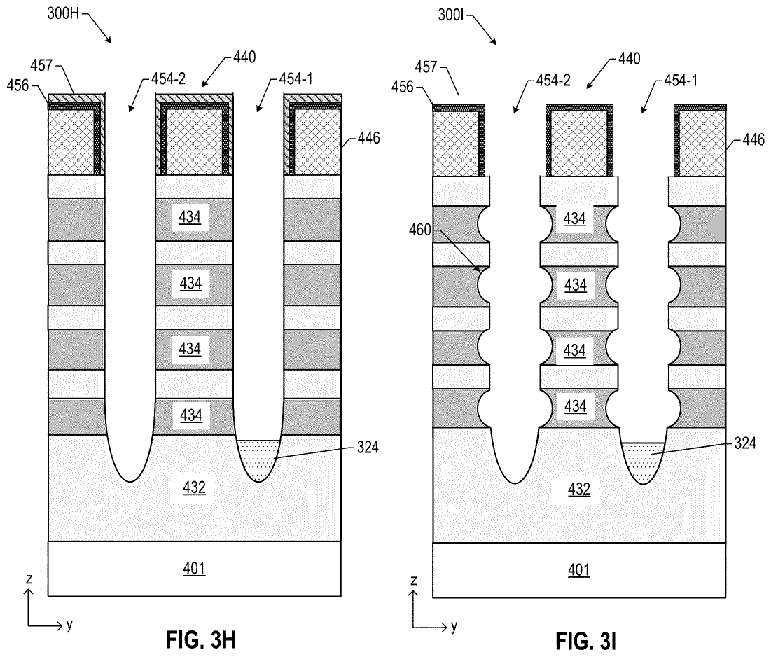

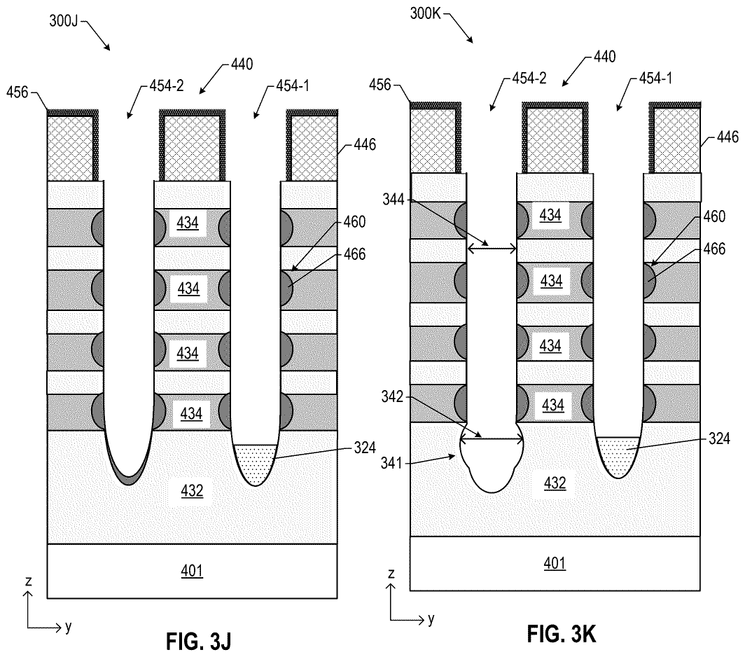

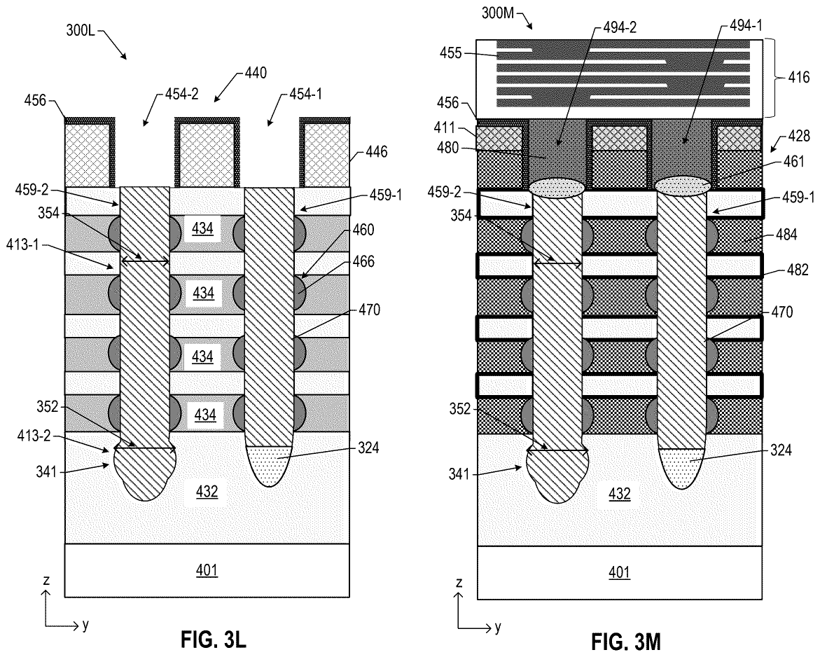

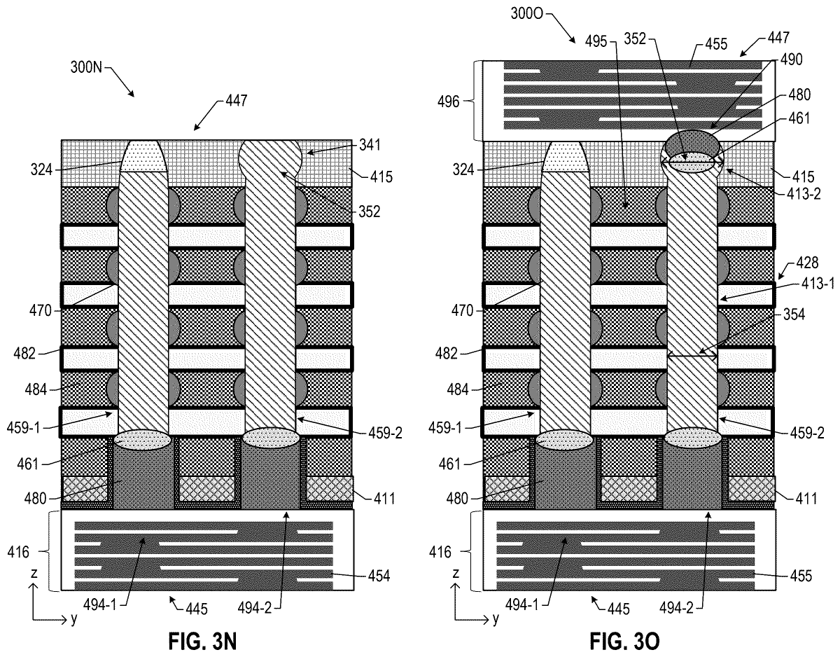

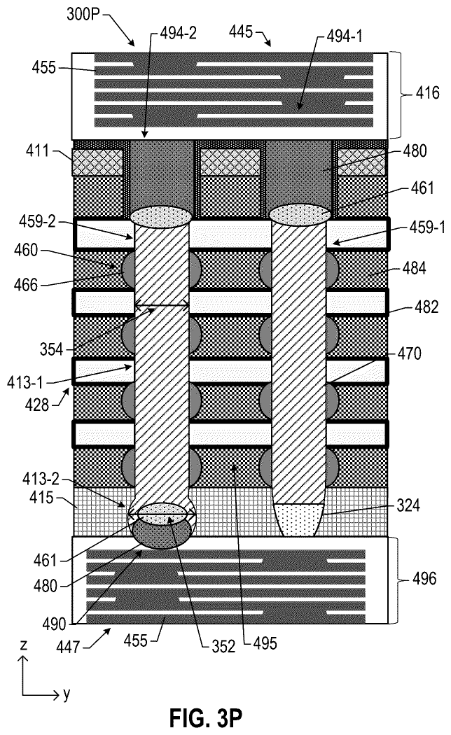

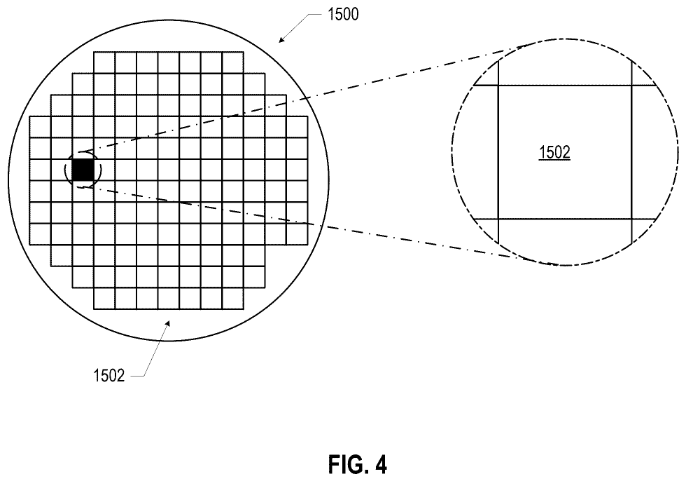

Nanoribbon transistors may be particularly advantageous for continued scaling of complementary metal-oxide-semiconductor (CMOS) technology nodes due to the potential to form gates on all four sides of a channel material (hence, such transistors are sometimes referred to as “gate all around” transistors). Therefore, some IC structures illustrated herein show nanoribbon transistors as an example (e.g., IC structures shown in FIG. 1, FIG. 3A-3C, and FIG. 4), although IC structures including a nanoribbon-based transistor with a wide S/D region below the nanoribbon stack as described herein may include other devices instead of or in addition to nanoribbon transistors, and are not limited to such transistors.

As used herein, the term “nanoribbon” refers to an elongated structure of a semiconductor material having a longitudinal axis parallel to a support structure (e.g., a substrate, a die, a chip, or a wafer) over which such a structure is built. Typically, a length of a such a structure (i.e., a dimension measured along the longitudinal axis, shown in the present drawings to be along the y-axis of an example x-y-z coordinate system 105 shown in FIG. 1) is greater than each of a width (i.e., a dimension measured along the x-axis of the coordinate system 105) and a thickness/height (i.e., a dimension measured along the z-axis of the coordinate system 105). In some settings, the terms “nanoribbon” or “nanosheet” have been used to describe elongated semiconductor structures that have a rectangular transverse cross-section (i.e., a cross-section in a plane perpendicular to the longitudinal axis of the structure), while the term “nanowire” has been used to describe similar elongated structures but with circular transverse cross-sections. In the present disclosure, the term “nanoribbon” is used to refer to all such nanowires, nanoribbons, and nanosheets, as well as elongated semiconductor structures with a longitudinal axis parallel to the support structures and with having transverse cross-sections of any geometry (e.g., transverse cross-sections in the shape of an oval or a polygon with rounded corners). A transistor may then be described as a “nanoribbon transistor” if the channel of the transistor is a portion of a nanoribbon, i.e., a portion around which a gate stack of a transistor may wrap around. The semiconductor material in the portion of the nanoribbon that forms a channel of a transistor may be referred to as a “channel material,” with source and drain regions of a transistor provided on either side of the channel material.

FIG. 1 provides a perspective view of an example IC structure 100 with a nanoribbon transistor 110, according to some embodiments of the present disclosure. As shown in FIG. 1, the IC structure 100 includes a semiconductor material formed as a nanoribbon 104 extending substantially parallel to a support 102. The transistor 110 may be formed on the basis of the nanoribbon 104 by having a gate stack 106 wrap around at least a portion of the nanoribbon referred to as a “channel portion” and by having source and drain regions, shown in FIG. 1 as a first S/D region 114-1 and a second S/D region 114-2, on either side of the gate stack 106. One of the S/D regions 114-1, 114-2 is a source region and the other one is a drain region. However, because, as is common in the field of FETs, designations of source and drain are often interchangeable, they are simply referred to herein as a first S/D region 114-1 and a second S/D region 114-2.

Implementations of the present disclosure may be formed or carried out on any suitable support 102, such as a substrate, a die, a wafer, or a chip. The support 102 may, e.g., be the wafer 1500 of FIG. 4, discussed below, and may be, or be included in, a die, e.g., the singulated die 1502 of FIG. 4, discussed below. The support 102 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support 102 may be a printed circuit board (PCB) substrate, a package substrate, an interposer, a wafer, or a die. Although a few examples of materials from which the support 102 may be formed are described here, any material that may serve as a foundation upon which an IC structure including a nanoribbon-based transistor with a wide S/D region below the nanoribbon stack as described herein may be built falls within the spirit and scope of the present disclosure. Although only one nanoribbon 104 is shown in FIG. 1, the IC structure 100 may include a stack of such nanoribbons where a plurality of nanoribbons 104 are stacked above one another. For example, FIG. 3P shows an IC structure that may be examples of the IC structure 100. In some embodiments, a portion of the support 102 right below the lowest nanoribbon 104 of the stack may be shaped as a subfin extending away from a base, as is known in the field of nanoribbon transistors.

The nanoribbon 104 may take the form of a nanowire or nanoribbon, for example. In some embodiments, an area of a transversal cross-section of the nanoribbon 104 (i.e., an area in the x-z plane of an x-y-z coordinate system 105 shown in FIG. 1, perpendicular to a longitudinal axis 120 of the nanoribbon 104) may be between about 25 and 10000 square nanometers, including all values and ranges therein (e.g., between about 25 and 1000 square nanometers, or between about 25 and 500 square nanometers). In some embodiments, a width of the nanoribbon 104 (i.e., a dimension measured in a plane parallel to the support 102 and in a direction perpendicular to the longitudinal axis 120 of the nanoribbon 104, e.g., along the x-axis of the coordinate system 105) may be at least about 3 times larger than a height of the nanoribbon 104 (i.e., a dimension measured in a plane perpendicular to the support 102, e.g., along the z-axis of the coordinate system 105), including all values and ranges therein, e.g., at least about 4 times larger, or at least about 5 times larger. Although the nanoribbon 104 illustrated in FIG. 1 is shown as having a rectangular cross-section, the nanoribbon 104 may instead have a cross-section that is rounded at corners or otherwise irregularly shaped, and the gate stack 106 may conform to the shape of the nanoribbon 104. The term “face” of a nanoribbon may refer to the side of the nanoribbon 104 that is larger than the side perpendicular to it (when measured in a plane substantially perpendicular to the longitudinal axis 120 of the nanoribbon 104), the latter side being referred to as a “sidewall” of a nanoribbon.

In various embodiments, the semiconductor material of the nanoribbon 104 may be composed of semiconductor material systems including, for example, N-type or P-type materials systems. In some embodiments, the nanoribbon 104 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the nanoribbon 104 may include a combination of semiconductor materials. In some embodiments, the nanoribbon 104 may include a monocrystalline semiconductor, such as silicon (Si) or germanium (Ge). In some embodiments, the nanoribbon 104 may include a compound semiconductor with a first sub-lattice of at least one element from group III of the periodic table (e.g., Al, Ga, In), and a second sub-lattice of at least one element of group V of the periodic table (e.g., P, As, Sb).

For some example N-type transistor embodiments (i.e., for the embodiments where the transistor 110 is an N-type metal-oxide-semiconductor (NMOS) transistor), the channel material of the nanoribbon 104 may include a III-V material having a relatively high electron mobility, such as, but not limited to InGaAs, InP, InSb, and InAs. For some such embodiments, the channel material of the nanoribbon 104 may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). For some example P-type transistor embodiments (i.e., for the embodiments where the transistor 110 is a P-type metal-oxide-semiconductor (PMOS) transistor), the channel material of the nanoribbon 104 may advantageously be a group IV material having a high hole mobility, such as, but not limited to Ge or a Ge-rich SiGe alloy. For some example embodiments, the channel material of the nanoribbon 104 may have a Ge content between 0.6 and 0.9, and advantageously may be at least 0.7.

In some embodiments, the channel material of the nanoribbon 104 may be a thin-film material, such as a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, if the transistor formed in the nanoribbon is a thin-film transistor (TFT), the channel material of the nanoribbon 104 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. In some embodiments, the channel material of the nanoribbon 104 may have a thickness between about 5 and 75 nanometers, including all values and ranges therein. In some embodiments, a thin-film channel material may be deposited at relatively low temperatures, which allows depositing the channel material within the thermal budgets imposed on back-end fabrication to avoid damaging other components, e.g., front-end components such as the logic devices.

A gate stack 106 including a gate electrode material 108 and, optionally, a gate insulator material 112, may wrap entirely or almost entirely around a portion of the nanoribbon 104 as shown in FIG. 1, with the active region (channel region) of the channel material of the transistor 110 corresponding to the portion of the nanoribbon 104 wrapped by the gate stack 106. As shown in FIG. 1, the gate insulator material 112 may wrap around a transversal portion of the nanoribbon 104 and the gate electrode material 108 may wrap around the gate insulator material 112.

The gate electrode material 108 may include one or more gate electrode materials, where the choice of the gate electrode materials may depend on whether the transistor 110 is a PMOS transistor or an NMOS transistor. In some examples, for a PMOS transistor, gate electrode materials that may be used in different portions of the gate electrode material 108 may include, but are not limited to, tungsten, ruthenium, palladium, platinum, cobalt, nickel, and conductive metal oxides (e.g., ruthenium oxide), conductive metal nitrides (e.g., titanium nitride). For an NMOS transistor, gate electrode materials that may be used in different portions of the gate electrode material 108 include, but are not limited to, tungsten, hafnium, zirconium, titanium, tantalum, aluminum, alloys of these metals, and carbides of these metals (e.g., hafnium carbide, zirconium carbide, titanium carbide, tantalum carbide, and aluminum carbide, titanium aluminum carbide). In one example in which both an NMOS transistor and a PMOS transistor include gate materials that include tungsten, the gate electrode material including tungsten for the NMOS transistor may include fluorine, and the gate electrode material including tungsten for the PMOS transistor may be fluorine-free (e.g., fluorine may be substantially absent from a gate electrode material including tungsten for a PMOS transistor). In some embodiments, the gate electrode material 108 may include a stack of a plurality of gate electrode materials, where zero or more materials of the stack are workfunction (WF) materials and at least one material of the stack is a fill metal layer. Further materials/layers may be included next to the gate electrode material 108 for other purposes, such as to act as a diffusion barrier layer or/and an adhesion layer.

In some embodiments, the gate insulator material 112 may include one or more high-k dielectrics including any of the materials discussed herein with reference to the insulator material that may surround portions of the transistor 110. In some embodiments, an annealing process may be carried out on the gate insulator material 112 during fabrication of the transistor 110 to improve the quality of the gate insulator material 112. The gate insulator material 112 may have a thickness that may, in some embodiments, be between about 0.5 nanometers and 3 nanometers, including all values and ranges therein (e.g., between about 1 and 3 nanometers, or between about 1 and 2 nanometers). In some embodiments, the gate stack 106 may be surrounded by a gate spacer, not shown in FIG. 1. Such a gate spacer would be configured to provide separation between the gate stack 106 and S/D contacts of the transistor 110 and could be made of a low-k dielectric material, some examples of which have been provided above.

Turning to the S/D regions 114-1, 114-2 of the transistor 110, in some embodiments, the S/D regions may be highly doped, e.g., with dopant concentrations of about 10²¹ cm⁻³, in order to advantageously form Ohmic contacts with the respective S/D contacts (not shown in FIG. 1), although these regions may also have lower dopant concentrations and may form Schottky contacts in some implementations. Irrespective of the exact doping levels, the S/D regions of a transistor are the regions having dopant concentration higher than in other regions, e.g., higher than a dopant concentration in the transistor channel (i.e., in a channel material extending between the first S/D region 114-1 and the second S/D region 114-2), and, therefore, may be referred to as “highly doped” (HD) regions. Even when doped to realize threshold voltage tuning as described herein, the channel portions of transistors typically include semiconductor materials with doping concentrations significantly smaller than those of the S/D regions 114-1, 114-2.

The S/D regions 114-1, 114-2 of the transistor 110 may generally be formed using either an implantation/diffusion process or an etching/deposition process. In the former process, dopants such as boron, aluminum, antimony, phosphorous, or arsenic may be ion-implanted into the nanoribbon 104 to form the source and drain regions. An annealing process that activates the dopants and causes them to diffuse further into the nanoribbon 104 may follow the ion implantation process. In the latter process, portions of the nanoribbon 104 may first be etched to form recesses at the locations of the future S/D regions 114-1, 114-2. An epitaxial deposition process may then be carried out to fill the recesses with material that is used to fabricate the S/D regions 114-1, 114-2. In some implementations, the S/D regions 114-1, 114-2 may be fabricated using a silicon alloy such as silicon germanium or silicon carbide. In some implementations, the epitaxially deposited silicon alloy may be doped in situ with dopants such as boron, arsenic, or phosphorous. In further embodiments, the S/D regions 114-1, 114-2 may be formed using one or more alternate semiconductor materials such as germanium or a group III-V material or alloy. And in further embodiments, one or more layers of metal and/or metal alloys may be used to form the S/D regions 114-1, 114-2. In some embodiments, a distance between the first and second S/D regions 114-1 and 114-2 (i.e., a dimension measured along the longitudinal axis 120 of the nanoribbon 104) may be between about 5 and 40 nanometers, including all values and ranges therein (e.g., between about 22 and 35 nanometers, or between about 20 and 30 nanometers).

The IC structure 100 shown in FIG. 1, as well as IC structures shown in other drawings of the present disclosure, is intended to show relative arrangements of some of the components therein, and the IC structure 100, or portions thereof, may include other components that are not illustrated (e.g., electrical contacts to the S/D regions 114-1, 114-2 of the transistor 110, additional layers such as a spacer layer around the gate electrode of the transistor 110, etc.). For example, although not specifically illustrated in FIG. 1, a dielectric spacer may be provided between a first S/D contact (which may also be referred to as a “first S/D electrode”) coupled to a first S/D region 114-1 of the transistor 110 and the gate stack 106 as well as between a second S/D contact (which may also be referred to as a “second S/D electrode”) coupled to a second S/D region 114-2 of the transistor 110 and the gate stack 106 in order to provide electrical isolation between the source, gate, and drain electrodes. In another example, although not specifically illustrated in FIG. 1, at least portions of the transistor 110 may be surrounded in an insulator material, such as any suitable interlayer dielectric (ILD) material. In some embodiments, such an insulator material may be a high-k dielectric including elements such as hafnium, silicon, oxygen, titanium, tantalum, lanthanum, aluminum, zirconium, barium, strontium, yttrium, lead, scandium, niobium, and zinc. Examples of high-k materials that may be used for this purpose may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In other embodiments, the insulator material surrounding portions of the transistor 110 may be a low-k dielectric material. Some examples of low-k dielectric materials include, but are not limited to, silicon dioxide, carbon-doped oxide, silicon nitride, organic polymers such as perfluorocyclobutane or polytetrafluoroethylene, fused silica glass (FSG), and organosilicates such as silsesquioxane, siloxane, or organosilicate glass.

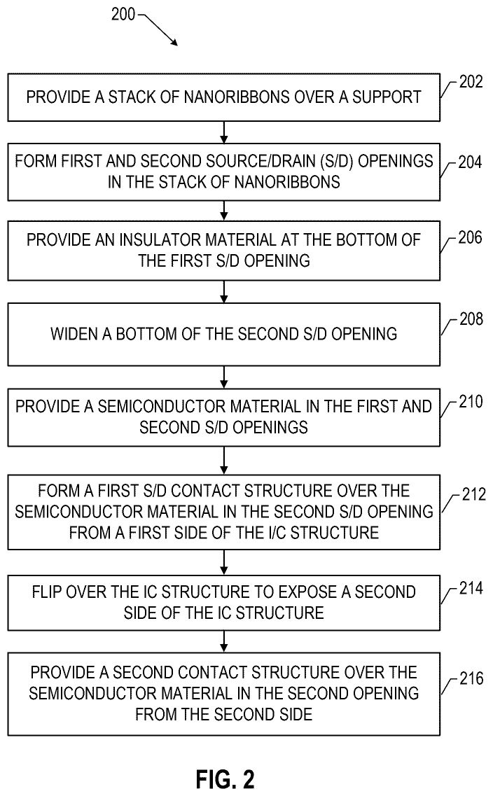

FIG. 2 is a flow diagram of an example method for fabricating an IC structure including a nanoribbon-based transistor with a wide S/D region below the nanoribbon stack, in accordance with some embodiments. FIGS. 3A-3P provide cross-sectional side views at various stages in the fabrication of an example IC structure according to the method of FIG. 2, in accordance with some embodiments.

Although the operations of the method of FIG. 2 are illustrated once each and in a particular order, the operations may be performed in any suitable order and repeated as desired. For example, one or more operations may be performed in parallel to fabricate multiple IC structures including a nanoribbon-based transistor with a wide S/D region below the nanoribbon stack substantially simultaneously. In another example, the operations may be performed in a different order to reflect the structure of an IC device in which IC structure including a nanoribbon-based transistor with a wide S/D region below the nanoribbon stack will be implemented.

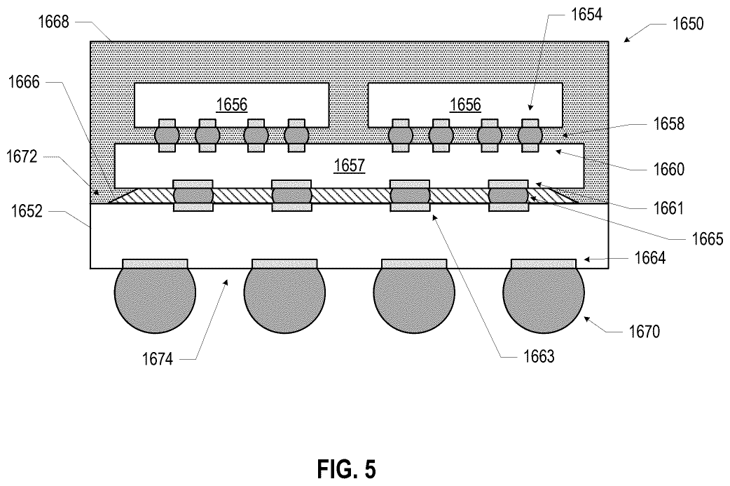

In addition, the example fabricating method of FIG. 2 may include other operations not specifically shown in FIG. 2, such as various cleaning or planarization operations as known in the art. For example, in some embodiments, a support, as well as layers of various other materials subsequently deposited thereon, may be cleaned prior to, after, or during any of the processes of the methods described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the intermediate IC structures described herein may be planarized prior to, after, or during any of the processes of the method of FIG. 5 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

Turning to FIG. 2, the method 200 begins with a process 202 of providing a stack of nanoribbons over a support. An IC structure 300A of FIG. 3A illustrates an example result of the process 202. For example, the IC structure 300A of FIG. 3A illustrates an example result of providing a stack of alternate layers of a semiconductor material and another material from a first side 445 of the IC structure 300A (e.g., a front side of the IC structure 300A, which may also be a front side of a wafer in or on which the IC structure 300A is formed). The IC structure 300A includes a support 401 and alternating layers of a semiconductor material 432 and layers of another material 434. While FIG. 3A illustrates five layers of the semiconductor material and four layers of the material 434 in a stack 402, in other embodiments, any other number of layers may be used as long as they are alternating and include at least three layers of the semiconductor material 432 and at least two layers of the material 434. The upper layers of the semiconductor material 432 will later be formed into nanoribbons stacked above one another. Thus, although a particular number of nanoribbons formed of the upper layers of the semiconductor material 432 is depicted in FIG. 3B (namely, four nanoribbons) and subsequent drawings, embodiments of the present disclosure include IC structures having more or fewer stacked nanoribbons than depicted.

As shown in FIG. 3A, in some embodiments, the alternation of layers of the semiconductor material 432 and the material 434 may begin after a bottom layer of the semiconductor material 432 is provided over the support 401. In one such example, the bottom layer of the semiconductor material 432 may later form a subfin under the stack of nanoribbons. Although the thickness of the bottom layer of the semiconductor material 432 is depicted as being greater than the subsequent layers of the semiconductor material 432 that are formed into nanoribbons via further processing, in other examples, the bottom layer of the semiconductor material 432 may have a substantially same thickness as another layer of the semiconductor material 432.

The semiconductor material 432 may be any of the semiconductor/channel materials described above with reference to the nanoribbon 104 of FIG. 1. The material 434 may be any suitable material that is etch-selective with respect to the semiconductor material 432 so that, in a later process, the material 434 may be etched away to form nanoribbons of the semiconductor material 432. As known in the art, two materials are said to be “etch-selective” (or said to have “sufficient etch selectivity”) with respect to one another when etchants used to etch one material do not substantially etch the other, enabling selective etching of one material but not the other. For example, in some embodiments, the semiconductor material 432 may be silicon while the material 434 may be a second semiconductor material such as silicon germanium. In another example, the semiconductor material 432 may be silicon germanium, while the material 434 may be silicon. In other examples, the material 434 may be made of a non-semiconductor material, e.g., of an insulator material, as long as this material is sufficiently etch-selective with respect to the semiconductor material 432.

Thus, the material 434 may be any suitable sacrificial material that is etch-selective with respect to the semiconductor material 432. Selecting the material 434 to be a semiconductor material may be particularly advantageous because it may improve the quality of the semiconductor material 432 if the semiconductor material 432 is epitaxially grown on the material 434. In some embodiments, the process may include epitaxially growing layers of the semiconductor material 432 and the material 434 (e.g., another semiconductor material) in an alternating manner. In other embodiments, alternate layers of the semiconductor material 432 and the material 434 may be provided in the process using other techniques, such as layer transfer or thin-film deposition. Although FIGS. 3A-3C illustrate the same semiconductor material 432 in various layers of the IC structures 300A-300C, in general, material compositions of a semiconductor material from which nanoribbons will later be formed in different layers of the IC structure 300A-300C may be different. For example, the semiconductor material 432 of one layer of the IC structure 300A may be silicon while the semiconductor material 432 of another layer of the IC structure 300A may be a III-N semiconductor material such as GaN.

FIG. 3B illustrates an example of an IC structure 300B resulting from the process of forming a fin from the stack of alternate layers of semiconductor material and another material. The IC structure 300B illustrates that the stack 402 of alternating layers of the semiconductor material 432 and the material 434 has been patterned into a fin 440. The fin 440 may include an active portion 441 and subfin portions 442. The active portions 441 may be a portion of the fin 440 from which nanoribbons will be formed, while the subfin portion 442 is a portion of the fin 440 that has sidewalls at least partially enclosed with an insulator material 436, e.g., as shown in FIG. 3B. The insulator material 436 may include any of insulator material typically used as a “shallow trench insulator” (STI) in fin-based or nanoribbon-based transistors, e.g., any suitable low-k dielectric material or other suitable insulator material.

Thus, the fin 440 may be shaped as a structure that extends away from the support 401 and may include a subfin 442 at the bottom, the subfin being a portion of the respective fin that is at least partially enclosed by an insulator material 436. In some embodiments, the subfin 442 may include the bottom layer of the semiconductor material 432, as well as an upper portion of the support 401, as is shown in FIG. 3B. However, in other embodiments, the subfin 442 may include only the semiconductor material 432 and not any portions of the support 401 (not shown in the present drawings). In some embodiments, semiconductor material 432 of the subfin 442 and/or the support 401 may be removed and/or replaced with one or more other materials in subsequent processes.

In the example illustrated in FIG. 3B, the fin 440 may have a width 443 (i.e., a dimension of the fin 440 measured along the x-axis of the example coordinate system shown in FIG. 3B). The width 443 may be that of the width of the nanoribbons subsequently formed (e.g., the nanoribbon 104 of FIG. 1 described above). The fin 440 may further have a length (i.e., a dimension of the fins 440 measured along the y-axis of the example coordinate system shown in FIG. 3B, where the y-axis is going into and coming out of the page) suitable to account for the length of the future nanoribbons (e.g., as described above with reference to the length of the nanoribbon 104 of FIG. 1).

In various embodiments, any suitable patterning techniques may be used to form the fin 440, such as, but not limited to, photolithographic or electron-beam (e-beam) patterning, possibly in conjunction with a suitable etching technique, e.g., a dry etch, such as e.g., RF reactive ion etch (RIE) or inductively coupled plasma (ICP) RIE. In some embodiments, the etch performed to form the fins 440 may include an anisotropic etch, using etchants in a form of e.g., chemically active ionized gas (i.e., plasma) using e.g., bromine (Br) and chloride (Cl) based chemistries. In some embodiments, during the etch to form the fins 440, the IC structure may be heated to elevated temperatures, e.g., to temperatures between about room temperature and 200 degrees Celsius, including all values and ranges therein, to promote that byproducts of the etch are made sufficiently volatile to be removed from the surface.

After forming the fin 440, a dummy gate material may then be provided around gate regions of the fin. FIG. 3C illustrates an example IC structure 300C resulting from the process of providing a dummy gate. The IC structure 300C illustrates the fin 440 over the support 401 and a material 446, which may be referred to as the dummy gate or replacement gate. In one example, the material 446 may be any suitable material such as polysilicon.

Referring again to FIG. 2, the method 200 continues with the process 204 of forming a first S/D opening and a second S/D opening in the stack of nanoribbons. FIG. 3D illustrates an IC structure 300D resulting from the process 204 from the perspective of the y-z plane in a cross-section along the fin 440. FIG. 3D illustrates a first opening 454-1 and a second opening 454-2 in the fin 440. Any suitable etching technique may be used to form the openings 454-1, 454-2, such as the techniques described above with respect to the process of forming the fins. In some embodiments, portions of the openings 454-1, 454-2 surrounded by the dummy gate material 446 may be lined with one or more liners, such as the liner 456 and the liner 457. The liners 456, 457 may include one or more of spacer materials, diffusion barrier materials, adhesion materials, etc., as known in the art for forming contacts to various components of IC structures. In one such example, the liner 456 may be an insulator material such as silicon nitride or silicon oxide. In one example, the liner 457 may be, for example, titanium nitride.

Referring again to FIG. 2, the method 200 continues with the process 206 of providing an insulator material at the bottom of the first S/D opening. Providing an insulator material at the bottom of one of the S/D openings may involve, for example, filling the S/D openings with a sacrificial material, forming a mask over the IC structure, removing the sacrificial material from one of the S/D openings, filling that opening with an insulator material, and recessing the insulator material to the desired level. FIG. 3E illustrates an IC structure 300E resulting from the process of filling the S/D openings with a sacrificial material 320. In one example, the sacrificial material 320 may be a carbon hard mask material or other suitable sacrificial material. FIG. 3F illustrates an IC structure 300F resulting from the process of providing a mask 322 over the IC structure 300F with an opening 323 over the S/D opening 454-1, and removing the sacrificial material 320 from the opening 454-1. The mask 322 may include multiple layers and may be formed using any suitable technique. The sacrificial material 320 may be removed using any suitable technique, e.g., an ashing process or other technique for removing the sacrificial material 320. FIG. 3G illustrates an IC structure 300G resulting from the process of filling the S/D opening 454-1 with an insulator material 324. The insulator material 324 may be, e.g., a flowable oxide (e.g., a flowable silicon oxide material), or any other suitable insulator material, and may be provided in accordance with any suitable deposition technique. FIG. 3H illustrates an IC structure 300H resulting from the process of recessing the insulator material 324 to below the bottom nanoribbon of the stack. In the example illustrated in FIG. 3I, the insulator material 324 is recessed to a level below the material 434 that will be replaced with the gate electrode material in a subsequent process.

In some examples, the method may then involve providing a spacer material at the sidewalls of the openings 454-1 and 454-2 to electrically insulate the S/D regions formed in the openings 454-1, 454-2 from the gate electrode material that may be provided in a subsequent process. In one such example, providing the spacer material may first involve recessing the material 434 at the sidewalls of the openings 454-1 and 454-2. FIG. 3I illustrates an example IC structure 300I resulting from the process of recessing the material 434 in the openings 454-1, 454-2. As can be seen in FIG. 3I, as a result of recessing the material 434, so-called “dimples” 460 may be formed in the sidewalls of the S/D openings 454-1, 454-2 in the fin 440, where the dimples 460 are areas in which the material 434 was recessed away from the original sidewalls of the openings 454-1, 454-2 (i.e., recessed laterally). Any suitable etching technique may be used in the process to recess the material 434 in the S/D openings 454-1, 454-2, such as any suitable wet etching technique using etchants that can etch the material 434 without substantially etching other materials of the IC structure 300I. The dimples 460 may have any suitable geometry and dimensions so that, when filled with an insulator material in a later process, the dimples 460 may provide electrical insulation between the material of the S/D regions that will be within the S/D openings 454-1, 454-2 formed in the fin 440 and the gate electrode material that will be present between the nanoribbons of the semiconductor material 432 formed from the fins 440. For example, a depth of the dimples 460, which is a dimension that is measured along the y-axis of the example coordinate system shown, may be between about 1 and 20 nanometers, e.g., between about 2 and 10 nanometers, or between about 3 and 7 nanometers. In the example illustrated in FIG. 3I, the liner 457 may also be removed.

FIG. 3J illustrates an example IC structure 300J resulting from the process of providing a spacer material in the openings 454-1, 454-2. As can be seen in FIG. 3J, the dimples 460 may be filled with a spacer material 466. Furthermore, the spacer material 466 may also line bottom of the opening 454-2. In the example illustrated in FIG. 3J, the spacer material is absent from the bottom of the opening 454-1 due to the presence of the insulator material 324 at the bottom of the opening 454-1. The spacer material 466 may include any suitable insulator material and be provided using any suitable deposition technique. In one example, the spacer material 466 is a different material, e.g., has a different material composition than the insulator material 324.

Referring again to FIG. 2, the method 200 continues with the process 208 of widening a bottom of the second S/D opening. FIG. 3K illustrates an IC structure 300K resulting from the process 208. As can be seen in FIG. 3K, the bottom 341 of the opening 454-2 has been widened and/or deepened. For example, the opening 454-2 has a width 342 at the bottom 341 portion that is greater than the width 344 in a top portion (e.g., a portion coplanar with the nanoribbons). Widening and/or deepening the bottom 341 of the opening 454-2 may involve any suitable etch process. In one example, a wet etch process that laterally etches the sidewalls of the opening 454-2 may be used.

Referring again to FIG. 2, the method 200 continues with the process 210 of providing a semiconductor material in the first and second S/D openings. FIG. 3L illustrates an IC structure 300L resulting from the process 210. As can be seen in FIG. 3L, the remaining portions of the openings 454 may be filled with respective S/D materials, shown as an S/D material 470 in the openings 454. The S/D materials 470 may include any materials for forming S/D regions (e.g., such as the S/D regions 114-1, 114-2 of FIG. 1) of nanoribbon-based transistors. In one example, the S/D material includes a doped semiconductor material. Techniques for filling S/D openings with an S/D material during fabrication of nanoribbon-based transistors are known in the art and, therefore, are not described here in detail. Thus, the IC structure 300L includes S/D regions 459-1, 459-2, where one of the regions 459-1, 459-2 is a source region and the other of the regions 459-1, 459-2 is a drain region. In the example illustrated in FIG. 3L, due to widening the bottom of the S/D opening 454-2, the S/D material 470 at the bottom of the region has a greater width 352 than a portion of the S/D material 470 that is coplanar with the nanoribbons (e.g., the width 352 is greater than the width 354).

In one example, after forming the S/D regions, the method can then involve the processes of removing the dummy gate material, releasing the nanoribbons, and providing a gate electrode material. Referring again to FIG. 2, the method 200 may also involve the process 212 of forming a first S/D contact structure over the semiconductor material in the second S/D opening from a first side of the I/C structure. FIG. 3M illustrates an example IC structure 300M resulting from the processes of removing the dummy gate material, releasing the nanoribbons, providing a gate electrode material, and forming front side S/D contacts. Removal of the dummy gate material 446 may include any suitable etching technique, provided the material of the dummy gate material 446 is sufficiently etch-selective with respect to the other materials of the IC structure 300L, in particular, with respect to the semiconductor material. Removing the dummy gate exposes the material 434 and the semiconductor material 432 at the sidewalls of the fin 440. An etch process may then be used to remove the material 434 from the fin 440, starting from the portions of the material 434 that are exposed by the removal of the dummy gate material 446. As a result of removing the material 434, a stack of nanoribbons of the semiconductor material 432 is formed from the fin 440. Thus, the nanoribbons of the stack are “released” in that the openings are formed around channel portions of the nanoribbons of the semiconductor material 432.

The gate electrode material 484 may be the same as, or similar to, the gate electrode material 108 described above with respect to FIG. 1. FIG. 3M further illustrates a gate insulator material 482 that may wrap around the gate regions of the nanoribbons of the stack. The gate insulator material 482 may be the same as or similar to the gate insulator material 112 described above with respect to FIG. 1. In some embodiments, the gate insulator material 482 may be absent in the IC structure 300M.

As can be seen in FIG. 3M, an S/D contact structure 494-1 is provided over the S/D material 470 of the S/D region 459-1 and an S/D contact structure 494-2 is provided over the S/D material 470 of the S/D region 459-2 from the first side 445 of the IC structure 300M. The S/D contact structures 494-1, 494-2 include an electrically conductive material 480 that fills the remainder of the openings 454-1, 454-2 and makes an electrical contact with the S/D material 470. The conductive material 480 may include, e.g., tungsten and/or another electrically conductive material. In the example illustrated in FIG. 3M, the IC structure 300M further includes an interface material 461 to provide an interface between the S/D material 470 of the S/D regions 459-1, 459-2 and the electrically conductive material 480 of the respective S/D contact structures 494-1, 494-2. The interface material 461 may include/be a metal such as titanium which, once deposited, may intermix with the material of the S/D regions 459-1, 459-2, e.g., with silicon, forming a compound (e.g., titanium silicide) that may help reduce contact resistance of the S/D contact structures 494-1, 494-2.

In some examples, an insulator material 411 may be provided over the gate electrode material 484 to prevent source/drain contacts to gate shorts. In some examples, contact structures for one or both of the S/D regions may be provided only from the back side. In one such example, the openings may be filled with an insulator material, such as the insulator material 411.

The IC structure 300M also includes interconnect layers 416 over the nanoribbons (e.g., over a device region 428 that includes the nanoribbons). As can be seen in FIG. 3M, the IC structure 300M includes the device region 428, and interconnect layers 416. A collection of interconnect layers such as the interconnect layers 416 may be referred to as a “metallization stack” of the IC structure 300M. Interchangeably, the metallization stack may be referred to as the “back end of line (BEOL) layer(s)” of the IC structure 300M, while the device region 428 may be referred to as the “front end of line (FEOL) layer(s)” of the IC structure 300M.

Electrical signals, such as power and/or input/output (I/O) signals, may be routed to and/or from the devices (e.g., the transistors) of the device region 428 through one or more interconnect layers disposed on the device region 428 (e.g., interconnect layers 416). For example, electrically conductive features of the device region 428 (e.g., the electrically conductive material 480 of the S/D contact structures 494-1, 494-2) may be electrically coupled with the interconnect structures 455 of the interconnect layers 416. The interconnect structures 455 may be arranged within the interconnect layers of the metallization stack to route electrical signals according to a wide variety of designs. Although a particular number of interconnect layers 416 is depicted in FIG. 3M, embodiments of the present disclosure include IC structures having more or fewer interconnect layers than depicted.

In some embodiments, the interconnect structures 455 may include conductive lines and/or conductive vias filled with an electrically conductive material such as a metal. The lines may be arranged to route electrical signals in a direction of a plane that is substantially parallel with a surface of the support 401 upon which the device region 428 is formed. For example, the lines may route electrical signals in a direction in and out of the page from the perspective of FIG. 3M. The vias may be arranged to route electrical signals in a direction of a plane that is substantially perpendicular to the surface of the support 401 upon which the device region 428 is formed. In some embodiments, the vias may electrically couple lines of different interconnect layers of the metallization stack together.

The interconnect layers 416 may include a dielectric material disposed between the interconnect structures 455. In some embodiments, the dielectric material disposed between the interconnect structures 455 in different ones of the interconnect layers 416 may have different compositions; in other embodiments, the composition of the dielectric material between different interconnect layers 416 may be the same.

Additional interconnect layers, as desired, may be formed in succession on the interconnect layers 416. In some embodiments, the interconnect layers that are “higher up” in the metallization stack in the IC structure 300M (i.e., farther away from the device region 428) may be thicker. Although not specifically shown in FIG. 3M, in some embodiments, the IC structure 300M may further include a solder resist material (e.g., polyimide or similar material) and one or more conductive contacts formed on the interconnect layers of the metallization stack.

Referring again to FIG. 2, the method 200 continues with the process 214 of flipping over the IC structure to expose a second side of the IC structure and a process 216 of providing a second contact structure over the semiconductor material in the second opening from the second side. Forming a contact structure from a second side of the IC structure (e.g., from a back side), may involve, e.g., removing a substrate and subfin and providing an insulator material around the exposed portions of the S/D regions. FIG. 3N illustrates an IC structure 300N resulting from the process 214 of flipping over the IC structure, removing the substrate and subfin, and providing an insulator material around the exposed S/D region portions. As can be seen in FIG. 3N, the IC structure 300N is flipped over to enable processing from the second side 447 of the IC structure 300N, and the substrate and subfin have been replaced with an insulator material 415. The insulator material 415 may be, for example, silicon oxide or another suitable insulator material. In other examples, the semiconductor material 432 of the subfin may not be replaced by an insulator material. In the example illustrated in FIG. 3N, a polish process has removed a portion of the insulator material 324 and the S/D material 470 of the S/D region 459-2 at the bottom of the S/D openings (e.g., where the bottom of the S/D openings are shown at the top of the IC structure 300N due to the IC structure 300N being flipped over).

Forming the second contact structure from the second side of the IC structure 300N may involve etching/recessing the exposed S/D material 470 from the second side 447, providing an interface material 461 on the S/D material 470, and providing an electrically conductive material 480 over the interface material 461. FIG. 3O illustrates an IC structure 300O with a second contact structure 490 (e.g., a backside contact structure), which includes the electrically conductive material 480. Although the contact structures 494-1, 494-2 and 490 are shown as including the same conductive material 480, in other examples the contact structure 490 may include a different conductive material than the contact structures 494-1, 494-2. Interconnect layers 496 may then be formed over the second side 447 of the IC structure 300°. The interconnect layers 496 may be similar to the interconnect layers 416 discussed above. In some examples, the taper direction of vias in the interconnect layers 416 may be opposite that of the vias in the interconnect layers 496. For example, vias of both the interconnect layers 416 and 496 may taper towards the nanoribbons of the device region 428. FIG. 3P illustrates an IC structure 300P oriented with the first side 445 (e.g., front side) of the IC structure 300P up (e.g., the IC structure 300P is flipped over relative to the IC structure 300°).

Performing the method 200 may result in features in the final IC structures that are characteristic of the use of the method 200. For example, one such feature is illustrated in the IC structure 300O shown in FIG. 3°, which shows a stack 495 of two or more nanoribbons stacked over one another, a region 459-2 of a doped semiconductor material in the stack where the region is either a source region or a drain region of a transistor, and where the region 459-2 includes a first portion 413-1 coplanar with the stack 495 (e.g., coplanar with one or more nanoribbons of the stack 495) and a second portion 413-2 below the stack 495 (e.g., in a subfin region). In one example, the first portion 413-1 has a first width 354, the second portion 413-2 has a second width 352, and the second width 352 is greater than the first width 354 (where the widths 352 and 354 are dimensions of the S/D region 459-2 in a plane substantially parallel with a nanoribbon of the stack). In one example, the second width 352 (e.g., the width of the enlarged portion 413-2) is about 10 to 45 percent greater than the first width 354 or about 15 to 40 percent greater than the first width 354. The IC structure 300O further includes a contact structure 490 (e.g., a backside contact structure) coupled with the second portion 413-2. In one example, the second portion 413-2 is below the gate electrode material (e.g., the large S/D portion is below the metal gate). Additionally, in the example illustrated in FIG. 3P, the doped semiconductor material (e.g., the S/D material 470) of the second portion 413-2 is coplanar with the conductive material 480 of the contact structure 490 (e.g., a portion of the doped semiconductor material is coplanar with the back side contact structure 490). In the example illustrated in FIG. 3P, sidewalls of the second portion 413-2 have a curved convex shape in a cross-section in a plane substantially orthogonal to a nanoribbon of the stack 495.

Another feature of the IC structure 300P is that the S/D region 459-2 extends further below the stack 495 than the region 459-1 (e.g., the S/D material 470 of the S/D region 459-2) extends further into the subfin region, e.g., closer to the backside metal layers, than the S/D material 470 of the S/D region 459-1. In one such example, an insulator material 324 may be present in the bottom of the S/D opening for the S/D region 459-1, e.g., below and substantially aligned with the second region and coplanar with the doped semiconductor material of the first region. In one such example, the insulator material 324 may be coplanar with the contact structure 490 (e.g., coplanar with the electrically conductive material 480 of the contact structure 490).

Another feature of the IC structure 300P is the absence of the spacer material (e.g., the spacer material 466 in the dimples 460) in the subfin regions of the S/D regions 459-1 and 459-2. For example, the insulator material/spacer material 466 on sidewalls of the S/D regions 459-1 and 459-2 is limited to areas between the gate electrode material 484 and the doped semiconductor material of the respective S/D region 459-1, 459-2 (e.g., the spacer material is absent from the S/D openings below the metal gate, e.g., absent from side walls below the gate and the bottom of the S/D regions).

IC devices/structures including a nanoribbon-based transistor with a wide S/D region below the nanoribbon stack as described herein (e.g., as described with reference to FIGS. 2 and 3A-3P) may be used to implement any suitable components. For example, in various embodiments, IC structures described herein may be part of one or more of: a central processing unit, a memory device (e.g., a high-bandwidth memory device), a memory cell, a logic circuit, input/output circuitry, a field programmable gate array (FPGA) component such as an FPGA transceiver or an FPGA logic, a power delivery circuitry, an amplifier (e.g., a III-V amplifier), Peripheral Component Interconnect Express (PCIE) circuitry, Double Data Rate (DDR) transfer circuitry, a computing device (e.g., a wearable or a handheld computing device), etc.

The IC devices and structures disclosed herein, e.g., the IC devices/structures 100 or 300P, or any variations thereof, may be included in any suitable electronic component.

FIGS. 4-7 illustrate various examples of apparatuses that may include any of the IC devices or structures disclosed herein.

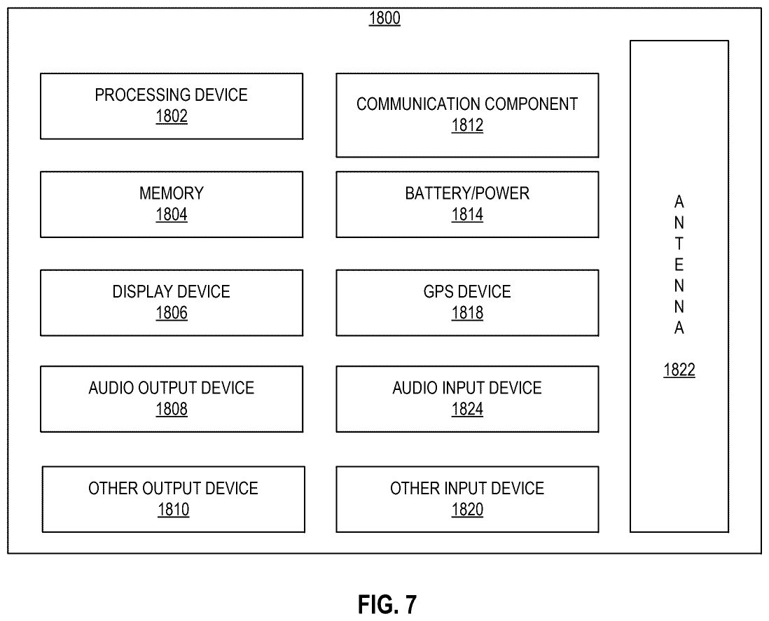

FIG. 4 is a top view of a wafer 1500 and dies 1502 that may include one or more IC structures in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more IC structures as described herein (e.g., any of the IC devices/structures 100 and 300P, described herein), one or more transistors (e.g., nanoribbon transistors of the IC devices/structures 100 and 300P) and/or supporting circuitry to route electrical signals to the transistors, as well as any other IC components. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 7) or other logic that is configured to store information in the memory devices or execute instructions stored in the memory array.

FIG. 5 is a side, cross-sectional view of an example IC package 1650 that may include one or more IC structures in accordance with any of the embodiments disclosed herein (e.g., any of the IC devices/structures 100 or 300P, described herein). In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 5 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 5 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

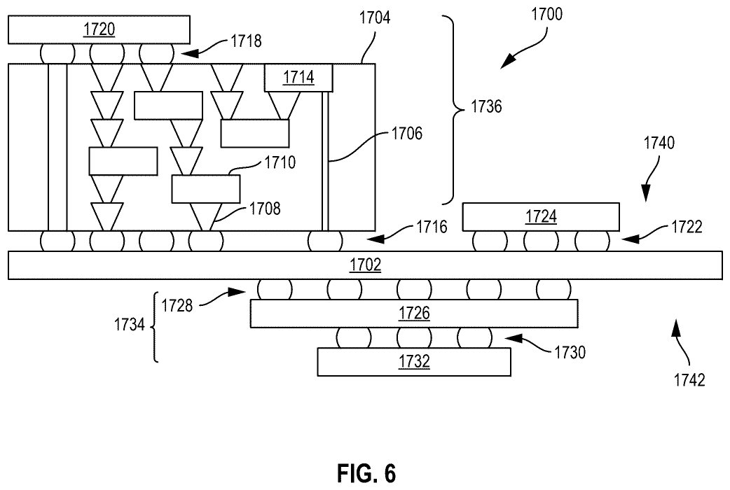

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 5 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 6.

The dies 1656 may take the form of any of the embodiments of the die 1502 discussed herein. In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high-bandwidth memory).

Although the IC package 1650 illustrated in FIG. 5 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 5, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 6 is a side, cross-sectional view of an IC device assembly 1700 that may include one or more IC packages or other electronic components (e.g., a die) including one or more IC devices in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 4 (e.g., may include one or more the IC devices/structures 100 or 300P).

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 6 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 6), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 6, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 4), an IC device (e.g., any of the IC devices/structures 100, or 300P, described herein, or any combination of such IC devices), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 6, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 6 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 7 is a block diagram of an example electrical device 1800 that may include one or more IC devices/structures 100 or 300P in accordance with any of the embodiments disclosed herein. For example, any suitable ones of the components of the electrical device 1800 may include one or more of the IC device assemblies 1700, IC packages 1650, or dies 1502 disclosed herein. A number of components are illustrated in FIG. 7 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 7, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic RAM (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic RAM (eDRAM) or spin transfer torque magnetic RAM (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP 2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include another output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra-mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 provides an IC structure, including a stack of two or more nanoribbons stacked over one another; a region of a doped semiconductor material in the stack (e.g., source region), where the region is either a source region or a drain region of a transistor, where: the region includes a first portion coplanar with the stack and a second portion below the stack, the first portion has a first width, the second portion has a second width, and the second width is greater than the first width; and a contact structure coupled with the second portion.

Example 2 provides the IC structure of example 1, further including a gate electrode material at least partially around the two or more nanoribbons, where the second portion is below the gate electrode material (e.g., the large portion of doped semiconductor material of the source region may be below the metal gate).

Example 3 provides the IC structure of any one of examples 1-2, where: the contact structure includes a conductive material, and the doped semiconductor material of the second portion is coplanar with the conductive material of the contact structure (e.g., a portion of the doped semiconductor material is coplanar with the back side contact structure).

Example 4 provides the IC structure of any one of examples 1-3, where: sidewalls of the second portion have a curved convex shape in a cross-section in a plane substantially orthogonal to a nanoribbon of the stack.

Example 5 provides the IC structure of any one of examples 1-4, where: the second width (e.g., the width of the big source epi) is about 10 to 50 percent greater than the first width (or about 15 to 40 percent greater).

Example 6 provides the IC structure of any one of examples 1-5, where the region is a first region, and where the IC structure further includes a second region (e.g., drain region) of the doped semiconductor material in the stack, where the doped semiconductor material of the first region extends further below the stack than the second region.

Example 7 provides the IC structure of example 6, further including a gate electrode material at least partially around the two or more nanoribbons; a first insulator material between the doped semiconductor material of the first region and the gate electrode material; and a second insulator material (e.g., a flowable oxide filling the bottom of the drain opening) below and substantially aligned with the second region and coplanar with the doped semiconductor material of the first region (e.g., a flowable oxide at the bottom of the drain opening may be coplanar with the doped semiconductor material of the source region).

Example 8 provides the IC structure of example 7, where: the second insulator material is coplanar with the contact structure (e.g., the flowable oxide at the bottom of the drain region may be coplanar with the back side source contact).

Example 9 provides the IC structure of any one of examples 7-8, where: the first insulator material on sidewalls of the second region is limited to areas between the gate electrode material and the doped semiconductor material (e.g., the spacer material is absent in the S/D regions below the metal gate, e.g., absent from side walls and the bottom of the drain region).

Example 10 provides the IC structure of any one of examples 1-9, where the contact structure is a first contact structure, and where the IC structure further includes a second contact structure coupled with the second portion.

Example 11 provides an IC structure, including a nanoribbon of a semiconductor material; a gate structure of a transistor, where the gate structure includes a conductive material at least partially around the nanoribbon; a source region of the transistor, where the source region includes a doped semiconductor material coupled with the nanoribbon; a drain region of the transistor, where the drain region includes the doped semiconductor material coupled with the nanoribbon, where: the doped semiconductor material of the source region extends further from the gate structure below that nanoribbon than the doped semiconductor material of the drain region; and a contact structure coupled with the source region below the nanoribbon.

Example 12 provides the IC structure of example 11, where: the source region includes a continuous portion of the doped semiconductor material coplanar with the nanoribbon and below the gate structure, the continuous portion has a first width coplanar with the nanoribbon and a second width below the gate structure, and the first width is smaller than the second width.

Example 13 provides the IC structure of any one of examples 11-12, further including a first insulator material (e.g., spacer) on sidewalls of the source region and the drain region between the conductive material and the doped semiconductor material; and a second insulator material (e.g., flowable oxide) below and substantially aligned with the drain region and coplanar with the doped semiconductor material of the source region, where the second insulator material is different from the first insulator material.

Example 14 provides the IC structure of example 13, where: the first insulator material is absent from sidewalls of the source region below the gate structure and from a bottom of the source region.

Example 15 provides the IC structure of any one of examples 14, where the sidewalls are first sidewalls and the bottom is a first bottom, and where: the first insulator material is absent from second sidewalls of the drain region below the gate structure and from a second bottom of the source region.

Example 16 provides the IC structure of example 13, further including a third insulator material below the gate structure between the doped semiconductor material and the second insulator material (e.g., the insulator material between the source region and a flowable oxide in the drain opening).

Example 17 provides the IC structure of example 16, where: a portion of the doped semiconductor material of the source region is between the third insulator material and the contact structure.

Example 18 provides the IC structure of any one of examples 11-17, where the contact structure is a first contact structure, and where the IC structure further includes a second contact structure coupled with the source region over the nanoribbon.

Example 19 provides an IC structure according to any one of examples 1-18, where the IC structure includes or is a part of a central processing unit.

Example 20 provides an IC structure according to any one of examples 1-19, where the IC structure includes or is a part of a memory device.

Example 21 provides an IC structure according to any one of examples 1-20, where the IC structure includes or is a part of a logic circuit.

Example 22 provides an IC structure according to any one of examples 1-21, where the IC structure includes or is a part of input/output circuitry.

Example 23 provides an IC structure according to any one of examples 1-22, where the IC structure includes or is a part of a field programmable gate array transceiver.

Example 24 provides an IC structure according to any one of examples 1-23, where the IC structure includes or is a part of a field programmable gate array logic.

Example 25 provides an IC structure according to any one of examples 1-24, where the IC structure includes or is a part of a power delivery circuitry.

Example 26 provides an IC package that includes an IC die including an IC structure according to any one of examples 1-25; and a further IC component, coupled to the IC die.

Example 27 provides an IC package according to example 26 where the further IC component includes a package substrate.

Example 28 provides an IC package according to example 26, where the further IC component includes an interposer.

Example 29 provides an IC package according to example 26, where the further IC component includes a further IC die.

Example 30 provides a computing device that includes a carrier substrate and an IC structure coupled to the carrier substrate, where the IC structure is an IC structure according to any one of examples 1-25, or the IC structure is included in the IC package according to any one of examples 26-29.

Example 31 provides a computing device according to example 30, where the computing device is a wearable or handheld computing device.

Example 32 provides a computing device according to examples 30 or 31, where the computing device further includes one or more communication chips.

Example 33 provides a computing device according to any one of examples 30-32, where the computing device further includes an antenna.

Example 34 provides a computing device according to any one of examples 30-33, where the carrier substrate is a motherboard.

Example 35 provides a method of fabricating an IC structure, the method including providing a stack of nanoribbons; forming a first opening and a second opening in the stack; providing an insulator material at a first bottom of the first opening below the stack; widening a second bottom of the second opening; providing a semiconductor material in the first opening over the insulator material and in the second opening from a first side (e.g., front side) of the IC structure; and flipping over the IC structure and forming a contact structure over the semiconductor material in the second opening from a second side (e.g., back side) of the IC structure opposite the first side.

Example 36 provides the method of example 35, where the contact structure is a first contact structure, and where the method further includes forming a second contact structure over the semiconductor material in the second opening from the first side (e.g., front side).

Example 37 provides a method according to any one of examples 35-36, where the IC structure is an IC structure according to any one of the preceding examples.

Example 38 provides a process of making an IC structure according to the method of any one of examples 35-37.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a stack of two or more nanoribbons stacked over one another;
a region of a doped semiconductor material in the stack, wherein the region is either a source region or a drain region of a transistor, wherein:
the region comprises a first portion coplanar with the stack and a second portion below the stack,
the first portion has a first width,
the second portion has a second width, and
the second width is greater than the first width; and
a contact structure coupled with the second portion.

2. The IC structure of claim 1, further comprising:
a gate electrode material at least partially around the two or more nanoribbons, wherein the second portion is below the gate electrode material.

3. The IC structure of claim 1, wherein:
the contact structure comprises a conductive material, and
the doped semiconductor material of the second portion is coplanar with the conductive material of the contact structure.

4. The IC structure of claim 1, wherein:
sidewalls of the second portion have a curved convex shape in a cross-section in a plane substantially orthogonal to a nanoribbon of the stack.

5. The IC structure of claim 1, wherein:
the second width is about 10 to 50 percent greater than the first width.

6. The IC structure of claim 1, wherein the region is a first region, and wherein the IC structure further comprises:
a second region of the doped semiconductor material in the stack, wherein the doped semiconductor material of the first region extends further below the stack than the second region.

7. The IC structure of claim 6, further comprising:
a gate electrode material at least partially around the two or more nanoribbons;
a first insulator material between the doped semiconductor material of the first region and the gate electrode material; and
a second insulator material below and substantially aligned with the second region and coplanar with the doped semiconductor material of the first region.

8. The IC structure of claim 7, wherein:
the second insulator material is coplanar with the contact structure.

9. The IC structure of claim 7, wherein:
the first insulator material on sidewalls of the second region is limited to areas between the gate electrode material and the doped semiconductor material.

10. The IC structure of claim 1, wherein the contact structure is a first contact structure, and wherein the IC structure further comprises:
a second contact structure coupled with the second portion.

11. An integrated circuit (IC) structure, comprising:
a nanoribbon of a semiconductor material;
a gate structure of a transistor, wherein the gate structure comprises a conductive material at least partially around the nanoribbon;
a source region of the transistor, wherein the source region comprises a doped semiconductor material coupled with the nanoribbon;
a drain region of the transistor, wherein the drain region comprises the doped semiconductor material coupled with the nanoribbon, wherein:
the doped semiconductor material of the source region extends further from the gate structure below that nanoribbon than the doped semiconductor material of the drain region; and
a contact structure coupled with the source region below the nanoribbon.

12. The IC structure of claim 11, wherein:
the source region comprises a continuous portion of the doped semiconductor material coplanar with the nanoribbon and below the gate structure,
the continuous portion has a first width coplanar with the nanoribbon and a second width below the gate structure, and
the first width is smaller than the second width.

13. The IC structure of claim 11, further comprising:
a first insulator material on sidewalls of the source region and the drain region between the conductive material and the doped semiconductor material; and
a second insulator material below and substantially aligned with the drain region and coplanar with the doped semiconductor material of the source region, wherein the second insulator material is different from the first insulator material.

14. The IC structure of claim 13, wherein:
the first insulator material is absent from the sidewalls of the source region below the gate structure and from a bottom of the source region.

15. The IC structure of claim 14, wherein the sidewalls are first sidewalls and the bottom is a first bottom, and wherein:
the first insulator material is absent from second sidewalls of the drain region below the gate structure and from a second bottom of the source region.

16. The IC structure of claim 13, further comprising:
a third insulator material below the gate structure between the doped semiconductor material and the second insulator material.

17. The IC structure of claim 16, wherein:
a portion of the doped semiconductor material of the source region is between the third insulator material and the contact structure.

18. The IC structure of claim 11, wherein the contact structure is a first contact structure, and wherein the IC structure further comprises:
a second contact structure coupled with the source region over the nanoribbon.

19. A method of fabricating an integrated circuit (IC) structure, the method comprising:
providing a stack of nanoribbons;
forming a first opening and a second opening in the stack;
providing an insulator material at a first bottom of the first opening below the stack;
widening a second bottom of the second opening;
providing a semiconductor material in the first opening over the insulator material and in the second opening from a first side of the IC structure; and
flipping over the IC structure and forming a contact structure over the semiconductor material in the second opening from a second side of the IC structure opposite the first side.

20. The method of claim 19, wherein the contact structure is a first contact structure, and wherein the method further comprises:
forming a second contact structure over the semiconductor material in the second opening from the first side.
